(19) United States
(12) Patent Application Publication
(10) Pub. No.: US 2024/0211646 A1
(43) Pub. Date: Jun. 27, 2024

(54) Real-Time Evaluator to Optimizing Prefab Retrofit Panel Installation

(71) Applicant: UT-Battelle, LLC, Oak Ridge, TN (US)

(72) Inventors: Diana HUN, Lenoir City, TN (US); Peter Lee-Shein WANG, Oak Ridge, TN (US); Nolan W. HAYES, Jefferson City, TN (US); Bryan Maldonado PUENTE, Knoxville, TN (US); Philip R. BOUDREAUX, Knoxville, TN (US); Stephen M. KILLOUGH, Knoxville, TN (US)

(21) Appl. No.: 18/509,721

(22) Filed: Nov. 15, 2023

Related U.S. Application Data
(60) Provisional application No. 63/425,823, filed on Nov. 16, 2022.

(51) Int. Cl. G06F 30/13

(52) U.S. Cl. CPC G06F 30/13

(57) ABSTRACT

A real-time evaluator decreases the cost of building envelope construction and retrofits by reducing the installation time for overclad panels and enhancing performance of the panels through higher installation quality. The real-time evaluator includes a machine vision subsystem to measure real-time locations of the panels as their being installed, a digital twin manager device to manage a current panel position digital twin based on the real-time measurements and make comparisons to a target panel position digital twin. The comparisons can be used to provide installation guidance to panel installers that can improve both the speed and accuracy of installation.

### BACKGROUND OF THE INVENTION

This invention was made with government support under Contract No. DE-AC05-00OR22725 awarded by the U.S. Department of Energy. The government has certain rights in the invention.

The present invention relates to systems and methods for facilitating installation of prefabricated panels.

Installation techniques for prefab components at a jobsite have experienced advances that include laser-based technologies, such as robotic total stations that expedite and improve the accuracy of building and land surveying. The advances also include 3D scanners that produce point cloud data for developing 3D models. These conventional tools are not being used for real-time corrections during installation that consider as-built measurements. Instead, these conventional tools are primarily used for as-built surveys, after the fact. For example, a survey of installed volumetric modules is sometimes performed that shows how much variance there is in the exterior faces. Often times these surveys reveal variances of an inch or more. These discrepancies reduce the ability to properly install certain features, such as a continuous air and water barrier. Some services are also available that perform tolerance verification using LIDAR measurements of a steel-framed chassis after it has been completely assembled. These services often reveal meaningful variances from the as-desired construction. Both of these examples demonstrate how conventional tools merely point out errors in construction or retrofit projects after the fact and often require expensive fixes to maintain the continuity of air and water barriers in a building envelope or to provide expected aesthetics of a façade.

According to the Precast/Prestressed Concrete Institute, about 50% of prefab wall projects for new construction have alignment problems. The prefab industry needs a digital tool that uses as-built measurements from these laser-based devices to provide corrective guidance at the time of installation that will improve the performance of the heat, air, and moisture barriers in the building envelope, increase productivity, and decrease rework.

### SUMMARY OF THE INVENTION

The present invention provides a system for guiding installation of overclad panels

on a building façade. The system can include a machine vision subsystem, a controller subsystem and a user interface subsystem.

The machine vision subsystem can track motion of panel targets relative to façade targets as an overclad panel equipped with the panel targets is brought towards, and installed at, a predetermined location of the façade equipped with the façade targets. The machine vision subsystem can also output a tracking signal indicative of positions of the panel targets relative to the façade targets. The machine vision subsystem can monitor live positions of the panel in six dimensions including X, Y, Z, roll, pitch, and yaw.

The panel targets and façade targets can be retroreflectors and the machine vision subsystem can include a laser-beam source, a beam scanning module, and an imaging module capable of tracking the retroreflector targets. The targets can be mechanical clamp optical targets vacuum fixture optical targets, or essentially any other trackable target. The targets can be disposed adjacent to connectors.

The controller subsystem can be communicatively coupled with the machine vision subsystem and configured to access, in a data source, a digital twin of the façade that includes façade local coordinates of the façade targets and of the predetermined installation location, a digital twin of the overclad panel that includes panel local coordinates of the panel targets, and one or more installation tolerances. The controller subsystem can also be configured to receive the tracking signal from the machine vision subsystem, ascertain, using the façade targets' local coordinates, the panel targets' local coordinates, and the tracking signal, whether the panel is positioned near the predetermined installation location within the installation tolerance, and if not so, determine a corrective motion of the panel relative to the façade to position the panel nearer the predetermined installation location, and issue corrective motion instructions actionable by an installer of the panel.

The user interface subsystem can be communicatively coupled with the controller subsystem and configured to receive the corrective motion instructions and issue them to the panel installer. The user interface subsystem can include a display module and/or speakers, and the corrective motion instructions can be presented to the panel installer using the display module and/or speakers. The corrective motion instructions can include a plurality of sequenced textual based instructions to guide the panel installer in moving the panel to the predetermined location, and each of the sequenced textual based instructions can be limited to instructions to move the panel in one dimension.

These and other objects, advantages, and features of the invention will be more fully understood and appreciated by reference to the description of the current embodiment and the drawings.

Before the embodiments of the invention are explained in detail, it is to be understood that the invention is not limited to the details of operation or to the details of construction and the arrangement of the components set forth in the following description or illustrated in the drawings. The invention may be implemented in various other embodiments and of being practiced or being carried out in alternative ways not expressly disclosed herein. Also, it is to be understood that the phraseology and terminology used herein are for the purpose of description and should not be regarded as limiting. The use of “including” and “comprising” and variations thereof is meant to encompass the items listed thereafter and equivalents thereof as well as additional items and equivalents thereof. Further, enumeration may be used in the description of various embodiments. Unless otherwise expressly stated, the use of enumeration should not be construed as limiting the invention to any specific order or number of components. Nor should the use of enumeration be construed as excluding from the scope of the invention any additional steps or components that might be combined with or into the enumerated steps or components. Any reference to claim elements as “at least one of X, Y and Z” is meant to include any one of X, Y or Z individually, and any combination of X, Y and Z, for example, X, Y, Z; X, Y; X, Z; and Y, Z.

### BRIEF DESCRIPTION OF THE DRAWINGS

FIG. 1 illustrates a real-time evaluator of the present disclosure for facilitating installation of prefabricated panels.

FIG. 2 illustrates generation of a building envelope portion of a target digital twin

from point cloud scan data.

FIG. 3 illustrates aspects of an autonomous tracking system for tracking prefabricated panels using optical targets.

FIG. 4 illustrates a positioning assistant device that can provide visual and/or auditory cues to an installation crew to facilitate installation of prefabricated panels.

FIGS. 5-11 illustrate a representative exemplary sequence of operations in real space and corresponding digital space to install a first panel onto a building façade of a building envelope while providing live guidance to the installation crew.

FIGS. 12-17 illustrate a representative exemplary sequence of operations in real space and corresponding digital space to install a second panel onto a building façade of a building envelope while providing live guidance to the installation crew.

FIGS. 18-21 illustrate a representative exemplary sequence of operations in real space and corresponding digital space to install a third panel onto a building façade of a building envelope while providing live guidance to the installation crew.

FIG. 22 illustrates an exemplary mechanical clamp retroreflector target.

FIG. 23 illustrates an exemplary vacuum fixture retroreflector target.

FIG. 24 illustrates an exemplary user interface for the positioning assistant device.

### DESCRIPTION OF THE CURRENT EMBODIMENT

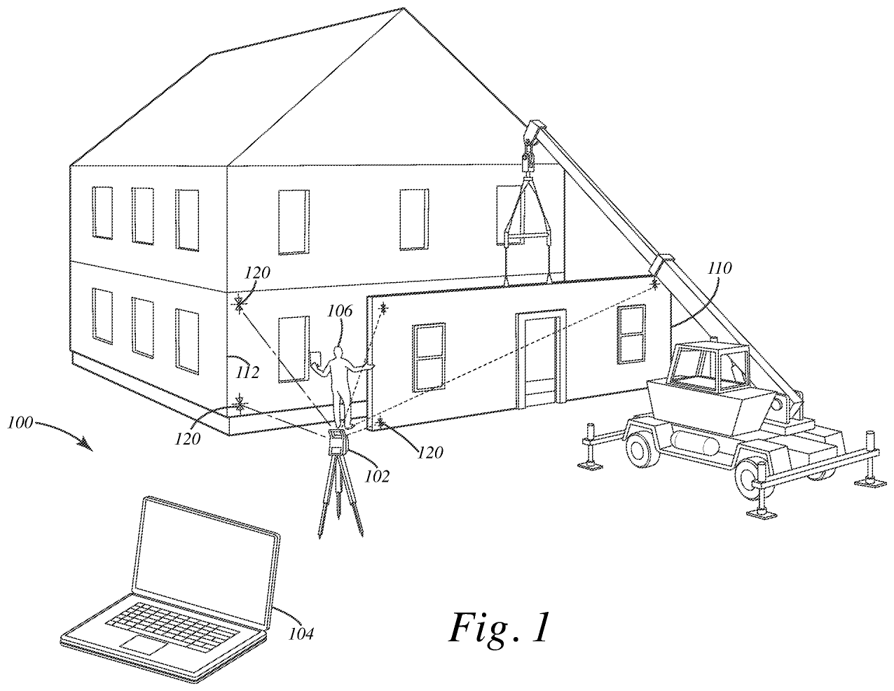

A real-time evaluator 100 in accordance with the present disclosure is shown in FIG. 1. The real-time evaluator can improve building envelope construction and/or modification (e.g., retrofitting an existing building envelope). For example, a real-time evaluator can reduce panel installation time and enhance panel performance through higher installation quality. In general, the real-time evaluator tracks real-world location data of a prefabricated panel 110 being installed (e.g., for new constructing or retrofitting a building) onto a building envelope 112, manages a virtual representation of the current position of the panel based on the real-world location data, and makes repeated comparisons to a virtual representation of the building with the installed panel as the panel is moved in the real-world. The virtual representation of the current position of the panel can be referred to as a current digital twin and the virtual representation of the building with the installed panel can be referred to as the target digital twin or goal digital twin. The comparisons between the current digital twin (which changes as the panel moves in the real-world) and the target digital twin can be used to provide live guidance to an installation crew while installing the panel.

A building envelope refers to the physical separator between a conditioned and unconditioned environment of a building including, for example, resistance to air, water, heat, light, and/or noise transfer. The building envelope may include the building façade as one of its components. A panel generally refers to a distinct section or component of a construction, often used in walls, ceilings, or exteriors. Panels can be made from various materials, including wood, metal, glass, or composite materials. Panels can provide insulation, soundproofing, or simply to add a decorative element to a building's façade. One type of panel is an overclad panel, which is used for overcladding. Overcladding is a process where a new layer of material is applied over existing cladding on a building. Overclad panels can be used to update or retrofit the exterior of a building, improve its thermal performance, or repair damage to the existing cladding, to name a few examples. Such panels can be made from materials like aluminum, steel, or composite materials and are often designed with insulation and weatherproofing properties. Overclad panels can have both aesthetic and functional qualities, as they can enhance a building's energy efficiency and protect it from environmental factors.

The real-time-evaluator 100 of the present disclosure includes a machine vision subsystem 102, a digital twin manager device 104, and a positioning assistant system 106. Optionally, the real-time evaluator 100 can include a digital twin generator system or the digital twin generation functionality (or portions thereof) can be integrated with the machine vision subsystem and/or the digital twin manager device. If target digital twin generation functionality is not provided by the real-time evaluator, then the real-time evaluator can be configured to receive the target digital twin from an external source, update the current digital twin based on the live machine vision information, and compare the updated current digital twin to the received target digital twin to generate installation guidance. The components of the real-time evaluator can be provided as subsystems, modules, devices, or the like that each can include their own set of sub-components.

### Digital Twin Generation

The digital twin generation functionality can include generating a target digital twin from scan data or model data. In general, the target digital twin can include two primary components, a virtual representation of a building envelope (or portion thereof) and a virtual representation of one or more retrofit panels. The building envelope component 204 of the target digital twin can be generated from point cloud data. The point cloud data can be obtained by placing temporary optical targets 120 about the building envelope and scanning the building envelope to obtain point cloud data (e.g., with a multi-robot station or 3D scanner). FIG. 1 illustrates two temporary optical targets 120 being disposed temporarily on the building, but depending on the portions being retrofit, additional optical targets may be disposed about the building envelope. In the case of a building construction project, as opposed to a retrofit project, the optical targets may be placed on or about the foundation of the building envelope (or building enclosure) where the panels will connect.

Local coordinates of the building envelope targets can be stored in a digital twin of the building envelope as well as one or more predetermined installation locations. For example, façade local coordinates of façade targets physically located on the façade of a building can be scanned and stored in a digital twin along with one or more predetermined installation locations for the panels. This digital twin can be referred to as a target digital twin and it can be stored in memory, such as a data source, that can be accessible by the digital twin manager device. Panel local coordinates of the panel targets can be stored in a digital twin of the panel. This digital twin can be referred to as a current digital twin because it maintains the current live (real-time or near real-time) position of the panel.

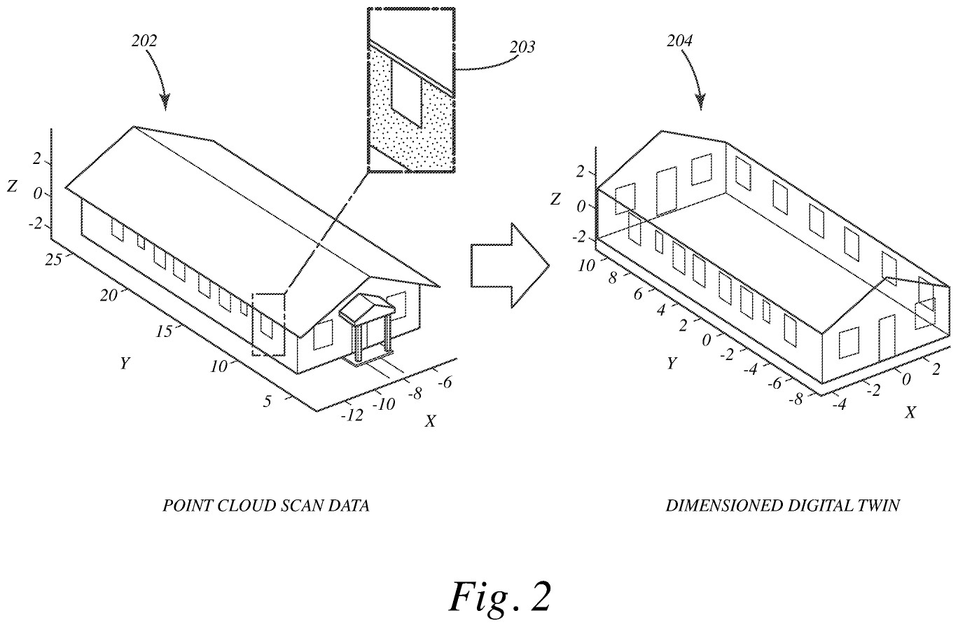

FIG. 2 illustrates representative point cloud scan data 202 of an exemplary building envelope. The close-up 203 illustrates how the point cloud scan data is composed of many different points, for example obtained by light detection and ranging (LIDAR), photogrammetry, or 3D laser scanning. In some embodiments, the scanning can be carried out by the machine vision subsystem 102 of the real-time evaluator and in other embodiments a separate scanning system can provide the scanning functionality. Optical targets can help to improve the accuracy of the scan by providing known points with precise coordinates that the digital twin generation system can use to calibrate and adjust measurements. Optical targets can also aid with alignment in the digital 3D space. For example, the targets can provide common reference points for aligning and merging separate scans into a single, cohesive point cloud. The optical targets also provide context for scale (e.g., dimensions) and orientation of the scan, for example to ensure that the XYZ, roll, pitch, and yaw dimensions of the building envelope component of the target digital twin are to scale and oriented accurately with respect to the panel component of the target digital twin and current digital twin.

The digital twin generator system can convert the point cloud scan data 202 of the building component into a building envelope digital twin component 204 using a scan-to-building information modeling algorithm (BIM) or other 3D reconstruction algorithm. In some embodiments, this conversion can be performed by the digital twin manager device 104 and in other embodiments the conversion is conducted by a digital twin conversion device that is part of a separate digital twin generation system.

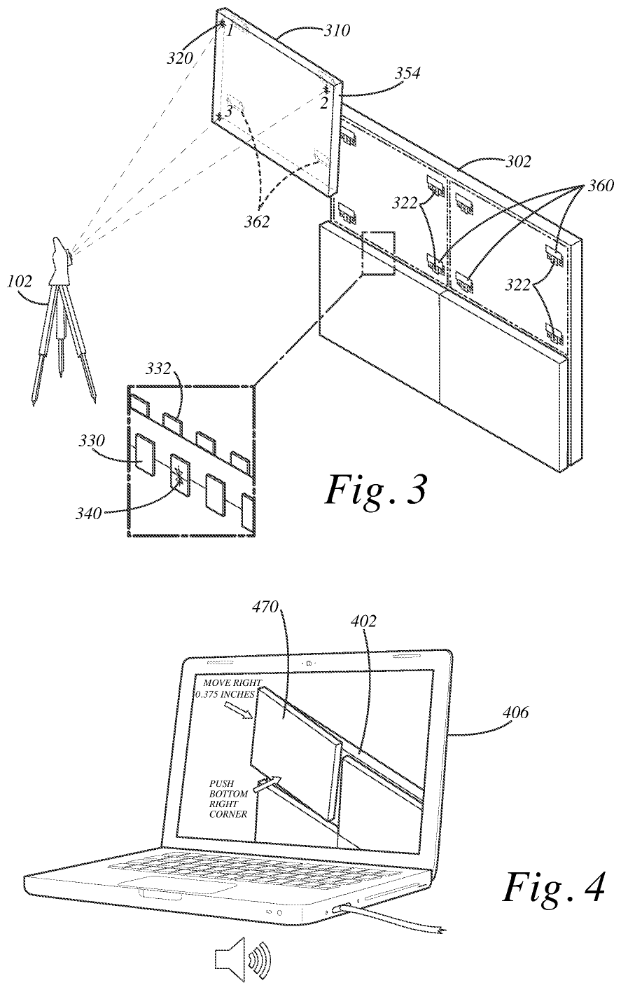

The virtual representation of the panel component 470 of the target and current digital twins can also be generated by scanning, with a machine vision subsystem 102 (or another scanning device), the panel 110, 310 and optical targets 120, 320 disposed about the panel, as depicted generally in FIGS. 3 and 4. Just as with the scanning of the building envelope, the optical targets 120, 320 associated with the panel 120, 320 can help to improve the accuracy, alignment, scale, and orientation of the panel component relative to the building envelope component in both the target digital twin and the current digital twin.

Alternatively, or in addition, the building envelope component 204 of the target digital twin can be generated or augmented based on one or more existing digital models of the building. For example, in some embodiments, the building envelope component 204 of the target digital twin can be generated using an existing building information model (BIM), e.g., one produced by an architect or engineer who is associated with the subject construction or retrofit project. That is, the virtual representation of the building envelope component 204 of the digital twin can be extracted from the BIM 3D drawings.

Alternatively, or in addition, the panel component 470 of the target digital twin can be generated or augmented based on one or more digital models of the panel. For example, the panel component 470 of the target digital twin depicted by the positioning assistant system 106 can be generated using dimensions of the panel 110, 310 or extracted from a 3D drawing of the panel 110, 310. In some embodiments, the target digital twin components can be generated by using a combination of both scan data and model data.

As part of the digital twin generation and digital twin management processes, resectioning can be conducted. Resectioning generally refers to determining the coordinates of an observer device position based on known points in the environment. For the real-time evaluator, resectioning can be conducted by referencing known points within the target digital twin, such as the coordinates of the optical targets, temporarily placed on the building. This allows the real-time evaluator to map the coordinates of the optical targets on the building to the positions of the optical targets represented in the digital twin and going forward to coordinate the coordinate systems in all six dimensions (X, Y, Z, pitch, roll, yaw). Should the machine vision subsystem be moved, it can be resectioned to synchronize the coordinate systems again.

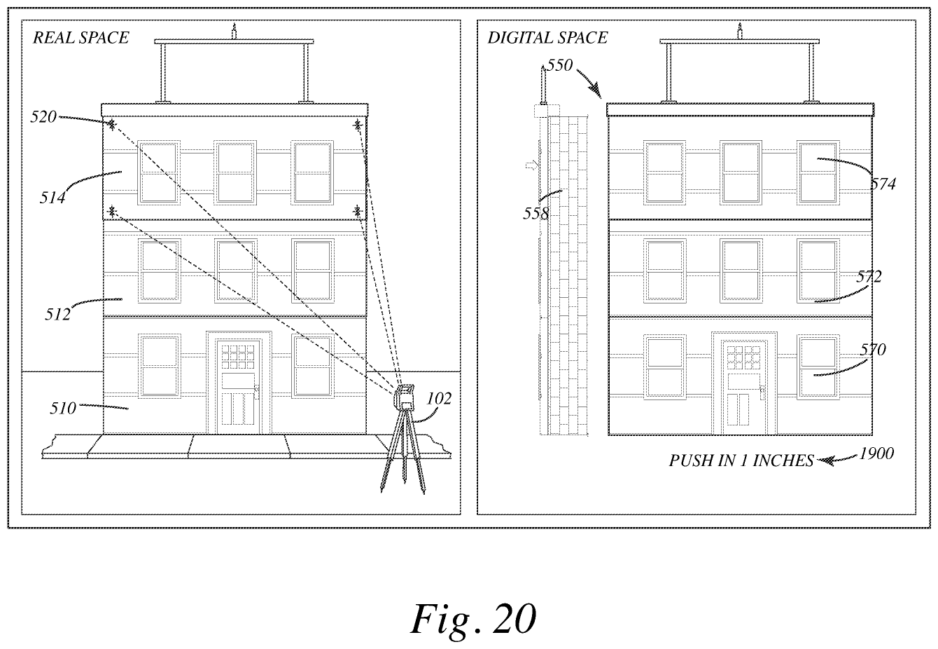

The target digital twin generation functionality includes virtually arranging the building envelope component 402 and the one or more panel components 470. That is, the target digital twin includes an arrangement of the one or more panel components 470 relative to (e.g., over) the building envelope 402 component in virtual 3D space, e.g., as set forth in as-designed drawings or as arranged digitally by a user using a 3D modeling software application. As will be discussed in more detail below, a visual representation of an exemplary target digital twin with three panels installed on a building envelope is illustrated in FIG. 20.

The target digital twin can also include an arrangement of virtual panel connections (with other panel components and/or the building envelope component) that match the desired arrangement of real-world panel connections (panel-to-panel and/or panel-to-building). For example, panel-to-panel connections 330, 332 can be a tongue-and-groove design where one panel has a set of protrusions along its edge that interconnect with slots in another panel that receive those protrusions. Further, as an example, panel-to-building connections can be cleat-style where a set of building-side connectors 360 are fastened to the face of the building envelope 302 such that corresponding panel-side connectors 362 on the back side of the panels 310 can facilitate connection between the panel 310 and the building envelope 302. Optical targets 322 can be placed on the building-side connectors. The digital twin manager can check that the building-side connectors 360 are correctly installed prior to beginning panel installation. That is, a comparison can be made between the actual location of the optical targets 322 of the building-side connectors and the as-designed or desired location of the connectors in the target digital twin.

The panel component and the building envelope components, along with their arrangement, are represented to scale in the virtual 3D space of the target digital twin. In some embodiments, instead of or in addition to the optical targets utilized on the face of the panel, optical targets are disposed on or within the panel connections (e.g., the outward facing portion of the protrusions). Such arrangement can enhance the guidance provided to users by the real-time evaluator by not only providing instructions as to how to manipulate the panel to reach its target pose in the target digital twin, but also about the status and quality of the panel connections based on the panel connector optical target feedback.

### Machine Vision Subsystem

The machine vision subsystem 102 can be configured to measure and store positions of a panel as it is being installed, perhaps as best shown in FIGS. 1 and 3. The machine vision subsystem can also be referred to as an autonomous tracking system. The positions obtained by the machine vision subsystem can be communicated to the digital twin manager device 104, e.g., via network cable, WiFi, Bluetooth, or another electronic communication interface. The machine vision subsystem 102 of the present disclosure includes a laser-beam source, a beam scanning module, and an imaging module. In some embodiments, the machine vision subsystem includes one or more surveying instruments, such as a robotic total station, laser tracker, and/or 3D scanner.

Optical targets 120, such as retroreflectors, can be installed on the panels 110, 302 to enhance tracking functionality. In cases in which panels can't be easily tracked from the ground or obstacles block the line-of-sight between the tracker and the retroreflectors, the autonomous tracking system 102 can include multiple trackers, and some placed at high elevations on adjacent buildings. In some embodiments, targets can be preinstalled on the panels (e.g., on the face of the panel or on at least some of the panel connections by the connection manufacturer) so that they are exposed and recognizable by the autonomous tracking system.

A laser tracker generally refers to a device that can accurately measure an object in three dimensions by determining the positions of optical targets joined thereto. The laser tracker generally works by projecting one or more laser beams to retroreflective targets at the object. The laser tracker measures the positions of the targets by analyzing the returned light.

A robotic total station (also referred to as a total station theodolite or multi total station) generally refers to an electronic/optical instrument used for surveying. It integrates an electronic transit theodolite with an electronic distance meter to measure vertical and horizontal angles and the slope distance from the instrument to a particular point, and an on-board computer to collect data and perform triangulation calculations. Robotic total stations can be operated remotely and can automatically track one or more retroreflector targets.

A 3D scanner generally refers to an electronic device that analyzes a real-world object or environment to collect data about its shape. The collected data can be used to construct digital three-dimensional models. 3D scanners can come in different forms, such as laser scanners, structured light scanners, and time-of-flight scanners. The 3D scanner can capture the geometry of an object (e.g., building envelope and/or panel), which involves collecting a series of data points from the object's surface. These data points can form a set of point cloud scan data 202 as shown in FIG. 2 and discussed above. The point cloud data 202 can be used to interpolate the shape of the object and create a digital 3D representation 204 by the digital twin manager device 104 (or a separate digital twin generation device). The 3D scanner can have programmable data collection speed. The accuracy of the 3D scanner can vary depending on the application, but an accuracy of +1/8-inch may be suitable. The 3D scanner can be configured to interface with a measurement component (e.g., laser tracker or robotic total station) to extract data and to command actions.

The autonomous tracking system 102 can track the position (e.g., in 6-dimensions: X, Y, Z, roll, pitch, and yaw) of the panels as they are being installed and update the current digital twin in a live fashion (e.g., real-time or near real-time) by outputting a tracking signal indicative of positions of the panel targets. The autonomous tracking system can (i) control a single robotic total station to cycle through, measure, and track multiple panel targets sequentially or (ii) control multiple laser trackers to each measure a single panel target to output the tracking signal. The tracking signal can be indicative of positions of the panel targets relative to the building envelope or building façade targets. It is worth noting that building envelope or building façade targets need not be present at the time the panel is being installed so long as the machine vision system was resectioned appropriately such that the relative coordinates of the building envelope/façade are known based on previously placed building envelope/façade targets. Alternatively, or in addition, the autonomous tracking system 102 can be configured to (i) locate panel connections after they have been installed on the building structure, and (ii) update the current digital twin accordingly.

### Digital Twin Manager Device

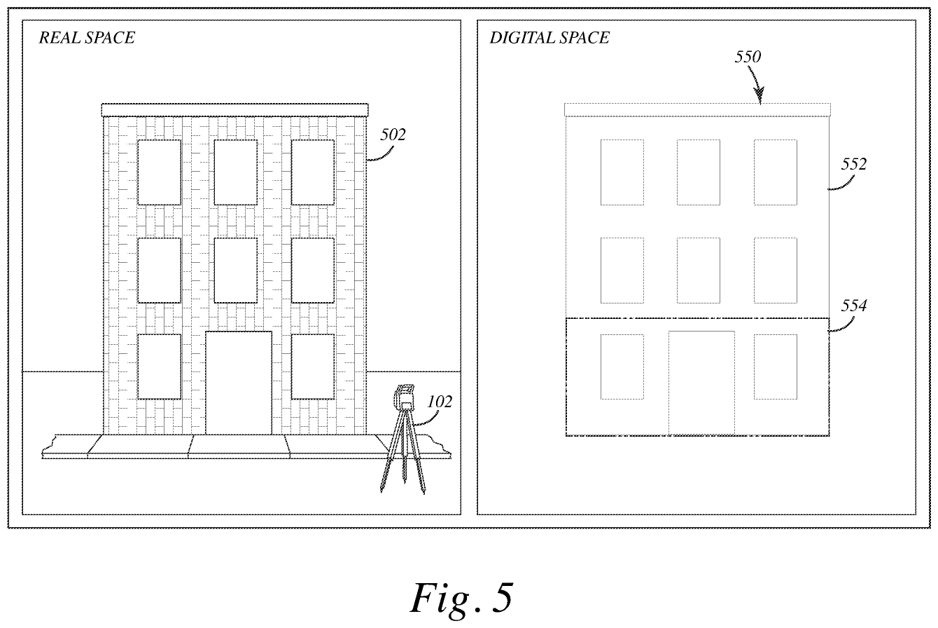

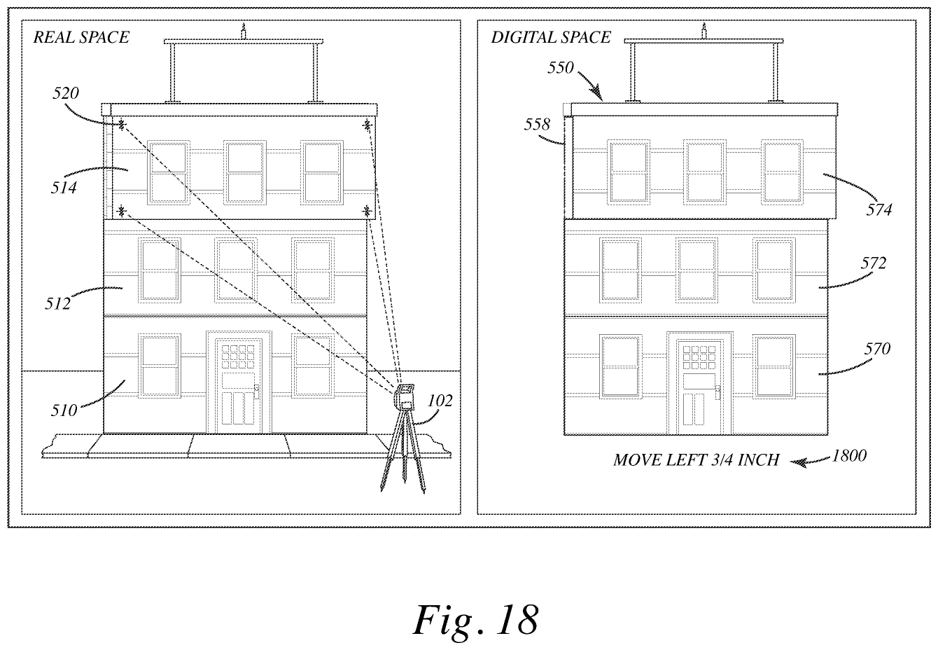

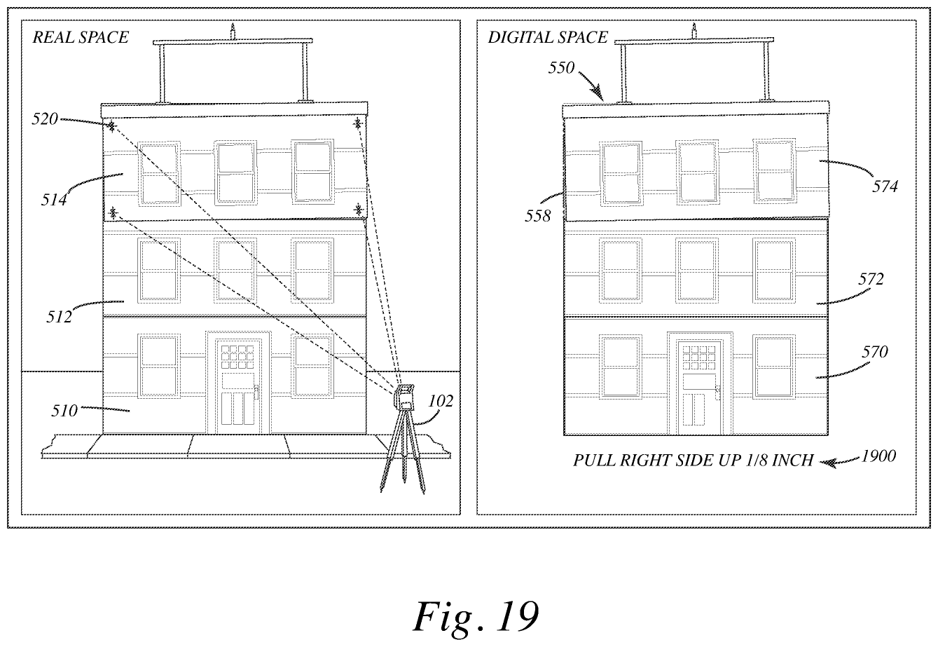

An exemplary digital twin manager device 104 is illustrated in FIG. 1 as a laptop having digital twin management software installed in memory, but any computing device with memory capable of executing software instructions for managing digital twins is suitable. A digital twin generally refers to a virtual representation of a physical object, process, or system over time, implemented using real-time data to mirror the structure, state, and behavior of the physical object. In general, the digital twin manager of the present disclosure manages a target digital twin and a current digital twin. The target digital twin virtually represents the desired or target arrangement of one or more panel components 470 relative to a building envelope component 204. It is worth noting this target digital twin need not include a visual representation of the building envelope component. In essence, the target digital twin includes coordinates of the one or more panel components relative to coordinates of the building envelope. The current digital twin virtually represents the current arrangement of one or more panel components 470 relative to a building envelope component 204. The desired target arrangement 354 for the real-world panel is shown in a representative fashion in FIG. 3 by a dashed outline of the edge of the target position of the panel. In the exemplary embodiment depicted in FIGS. 5-22, the target digital twin shows a virtual representation of a building envelope and target positions, e.g., coordinates, of panels with respect to the building envelope component. In essence, the digital twin manager device 104 maintains a current digital twin that includes the live position of the panel component(s) and compares that against the target digital twin to determine position deviations of the panel and generate instructions for moving the panel in the current digital twin to reach the positional state in the target digital twin.

The digital twin manager device 104 can be programmed to provide live updates (e.g., real-time or near real-time) of the current digital twin based on the tracking information provided by the autonomous tracking system 102. For example, the digital twin manager device 102 can be programmed to calculate and render a digital representation of the building envelope and a movable digital representation of the panel(s) such that during operation of the RTE, the digital twin can be updated using the current locations of the panels (and/or its connections) based on the live panel location information received from the autonomous tracking system.

### Positioning Assistant System

The positioning assistant system 106 can provide guidance to one or more installation crew members to facilitate installation at its proper location relative to the building envelope. The positioning assistant system 106 can include one or more positioning assistant devices that each include a user interface configured to provide visual and/or auditory guidance information received from the digital twin manager device 104. Each positioning assistant system can include a user interface subsystem that includes a display module, speaker module, or other feedback module. Corrective motion instructions can be presented to a panel installer using the display module, speaker module, or any other suitable module of the user interface subsystem. For example, one or more installation crew members can have positioning assistant devices in communication with the digital twin manager device 104. Perhaps as best shown in FIG. 4, each positioning assistant device 406 can include a user interface configured to display a 3D representation of the panel 402 on a screen of a positioning assistant device as well as one or more instructions to move the panel into its target position. For example, the user interface of device 406 can provide instructions to “move right 0.375 inches” and “push bottom right corner”. As the installation crew adjusts the panel according to these instructions, the instructions can be updated in real-time until the panel is positioned within a set of tolerances. Alternatively, or in addition, each positioning assistant device 406 can include one or more speakers, and corrective motion instructions can be presented to a panel installer using the speakers. Such instructions (whether auditory, visual, or both) can reduce panel installation time and cost significantly.

The user interfaces of the devices of the positioning assistant system 106 can vary depending on the application and use case. In some embodiments, the user interface provides sequenced textual guidance in the form of short, easy to understand commands. In other embodiments, the user interface provides a visual depiction (e.g., an animation) showing the guidance being commanded. This can be in addition to or instead of the textual guidance. These user interfaces are particularly suited for installation crew members with smart phones or tablets that are in the field ready to move the panels into their installation positions and need to have easy access to the guidance instructions.

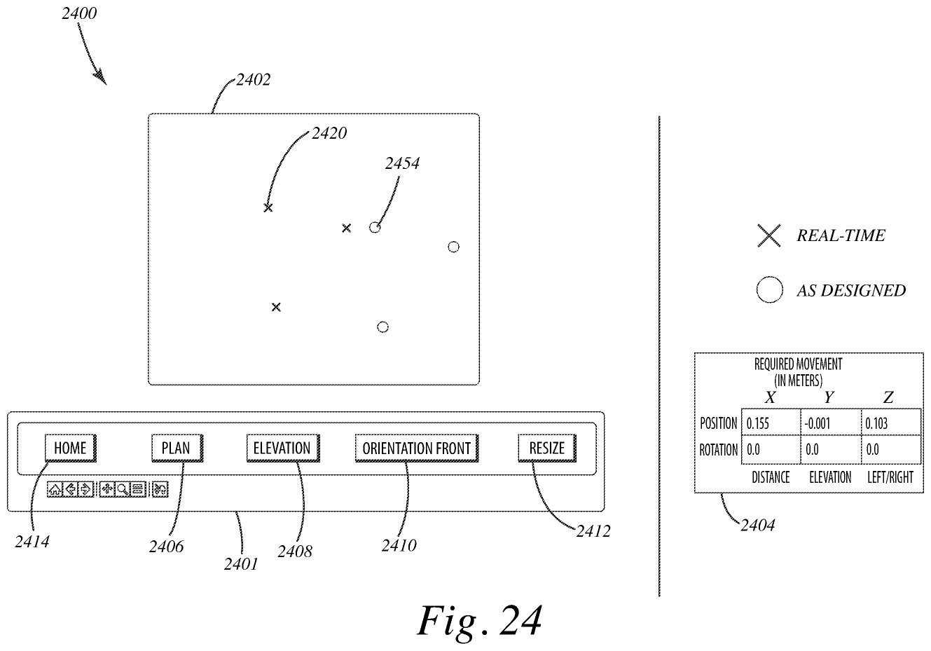

In other embodiments, the user interface provides a more robust and full-featured user interface experience. For example, FIG. 24 illustrates an exemplary user interface 2400 of a positional assistant device of the positioning assistant system 106. The user interface can include two primary components: 1) a view control panel 2401; and 2) a viewing area 2402 depicting a visual representation of the target digital twin and current digital twin controllable by the view control panel. As discussed above, the RTE can track the retroreflective targets coupled to a panel to determine a set of movements in 6-dimensions to align the current position of the panel (represented by the Xs 2420) with a target panel position (represented by Os 2454). As the physical, real-world panel is moved, the Xs in the user interface move relative to the position of the Os. Optionally, a legend 2404 can be provided that includes the movements in each of the 6 dimensions to align the current position of the panel with its target position.

The view control panel 2401 of the user interface 2400 can be used to manipulate the view shown in the viewing area 2402. For example, the plan 2406, elevation 2408, and orientation front 2410 buttons can be used to orient the user's view in the viewing area 2402 accordingly. The resize button 2412 can be used to resize the objects in the viewing area while maintain their relative scale. The home button 2414 can revert the viewing area 2402 back to a default view. Other view controls or tools to enhance the user experience and make interaction with the target digital twin and current digital twin as intuitive and informative as possible. For example, such controls/tools can include panning, zooming, rotating or orbiting, tilting, hiding/showing components, and measuring to name a few.

Although the depicted user interface 2400 includes a viewing area that depicts virtual representations of the optical targets 2420 and their target positions 2454, in alternative embodiments, representations of the panel and/or building envelope can be included in the viewing area 2402 based on the positions of the optical targets 2420 and their target positions 2454. For example, the panel and building envelope structure/outline can be selectively hidden or shown using a button in the view control panel.

### Exemplary 3-Panel Installation

FIGS. 5-22 illustrate a representative exemplary sequence of operations in real space and corresponding digital space to install three panels onto a building façade of a building envelope. Referring to FIG. 5, in the real space, a building envelope 502 is provided that has a corresponding target digital twin 550 in the digital space. The target digital twin 550 includes a building envelope component 552 and a panel component 554. In this embodiment of the disclosure, the building envelope component 552 is depicted as an outline showing its general shape while the panel component 554 is represented with a dashed outline about its outer border representing the target position of the real world panel relative to the real world building envelope.

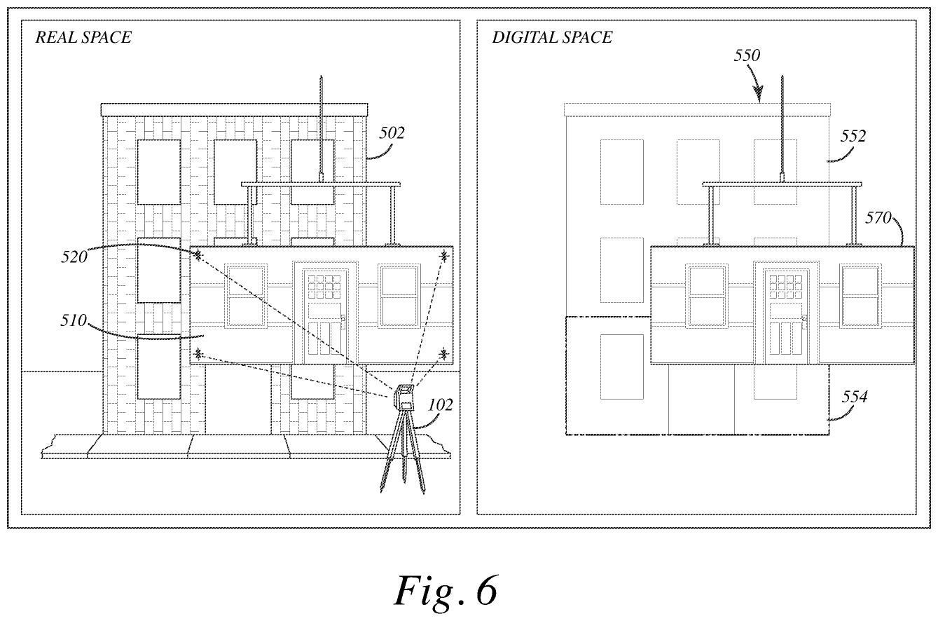

Referring to FIG. 6, as the first panel 510 having optical targets 520 disposed temporarily thereon moves within view of the automatic tracking device 102 it communicates tracking data to the digital twin manager device (not shown). The digital twin manager device updates the current digital twin to reflect to the current position of the panel 570 in the corresponding digital space. The digital twin manager device also compares the current digital twin to the target digital twin to determine whether or not guidance instructions should be communicated to the positioning assistant system. Regardless of whether guidance instructions are communicated, visual information may be communicated to the positioning assistant device, which can be displayed on the user interface to show the relative visual position of the panel 570 to its target position 554 in the target digital twin. In essence, the digital space can represent the visual information communicated to the positioning assistant device.

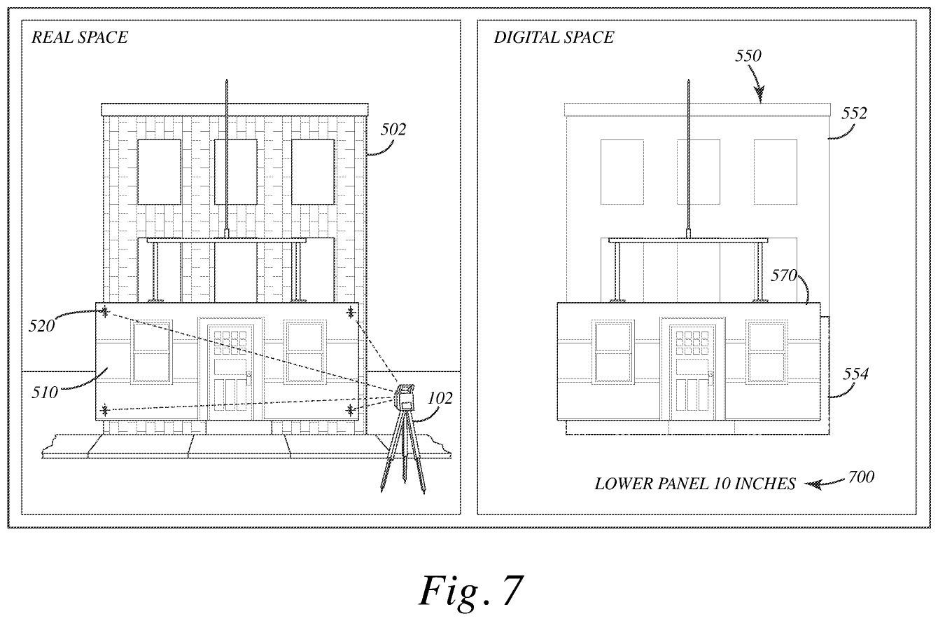

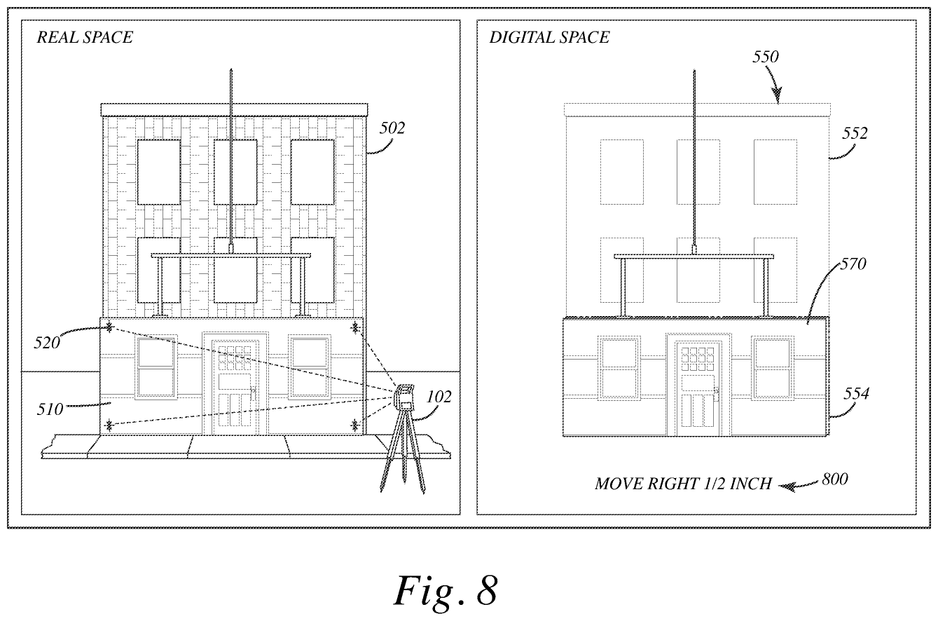

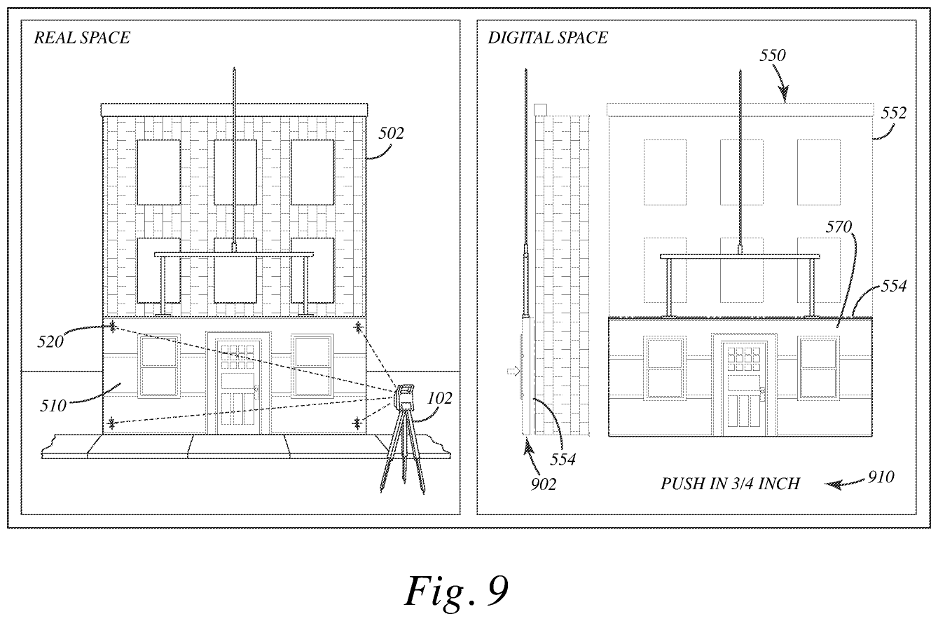

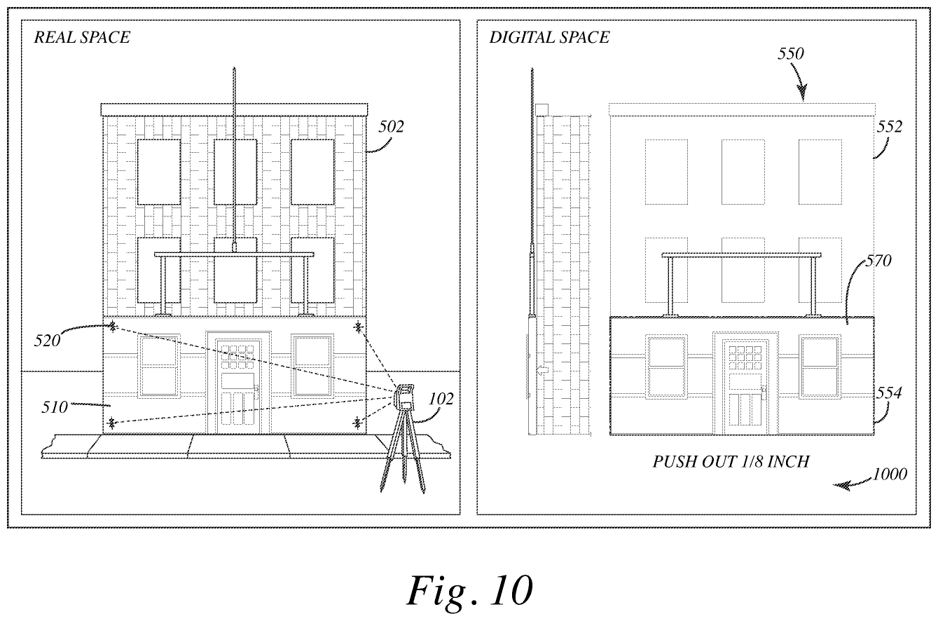

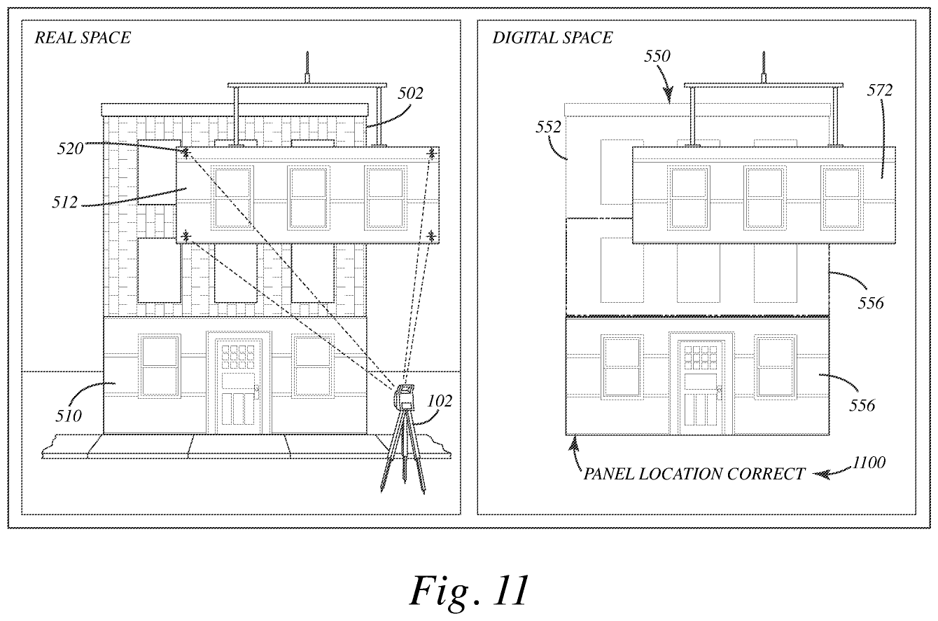

Referring to FIGS. 7-11, as the panel 510 is moved closer to its target position 554 the digital twin manager device continues to update the virtual representation of the panel 570 based on measurements from the automatic tracking device 102 of the real world panel 510 (e.g., from the retroreflectors 520) and evaluates whether the panel component 570 of the current digital twin is sufficiently close to the target panel component position 554 of the target digital twin 550 to begin providing guidance, and if so what guidance to provide. In FIG. 7, the digital twin manager device provides an instruction 700 to the installation crew, via communication to the positioning assistant system, to “LOWER PANEL 10 INCHES”. In FIG. 8 an instruction is provided to “MOVE RIGHT ½ INCH.” In FIG. 9, an instruction is provided to “PUSH IN ¾ INCH” and in FIG. 10 to “PUSH OUT ⅛ INCH.” The digital twin manager device can be configured to provide instructions in sequence so as not to overwhelm the installation crew with conflicting or confusing instructions. Referring to FIG. 11, once the panel component 570 of the current digital twin is positioned within certain tolerance ranges for the 6-dimensions (e.g., within 0.125 inches of the target for the X, Y and Z coordinates and within 0.125 degrees of the target for the pitch, roll, and yaw), an indication 1100 can be provided to the user that the panel location is correct and the optical targets 520 can be removed from the panel 510. The tolerance ranges can vary depending on the application. In some embodiments, the tolerance ranges can be dynamically set by the user in the user interface of the positional assistant device.

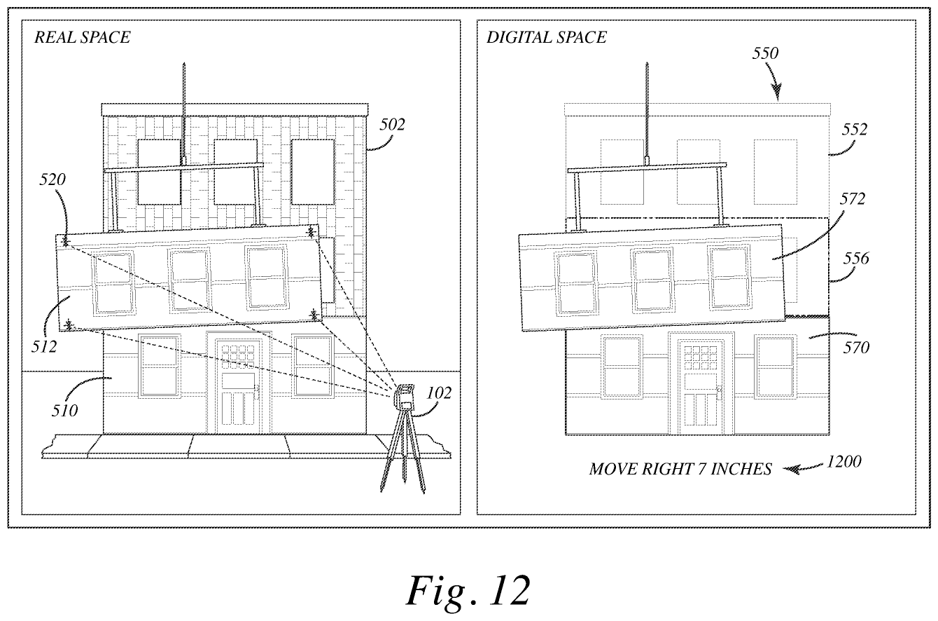

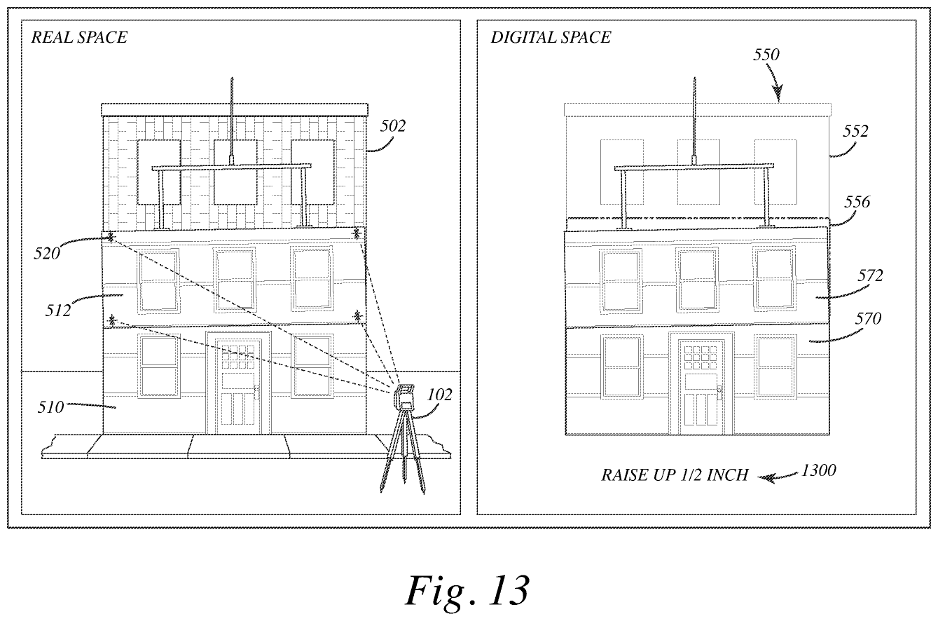

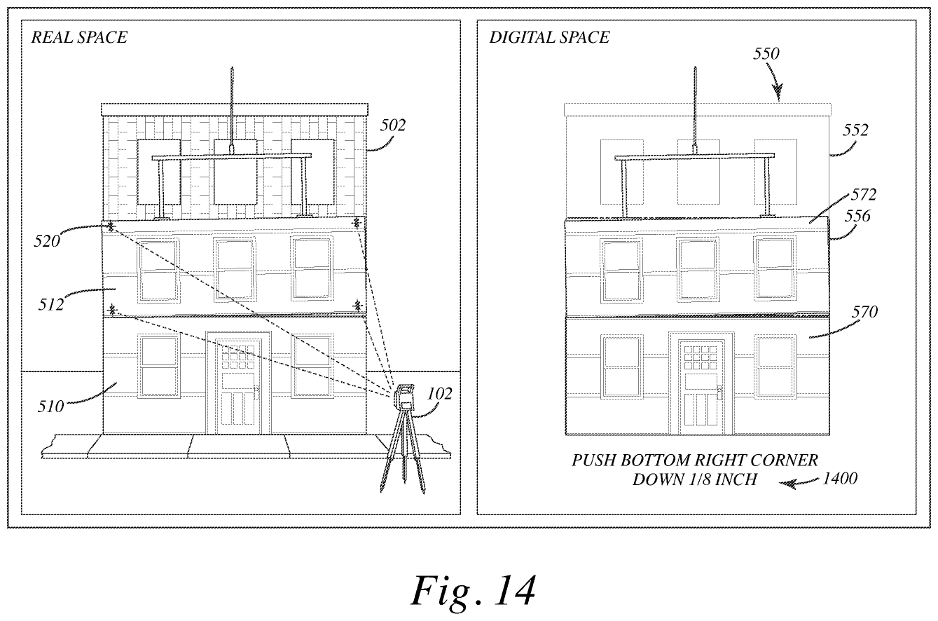

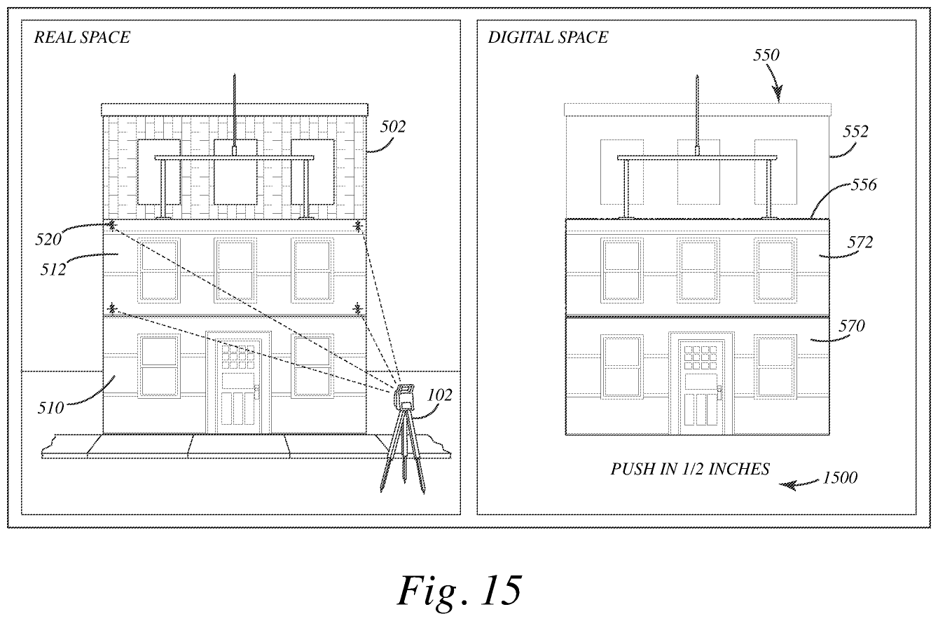

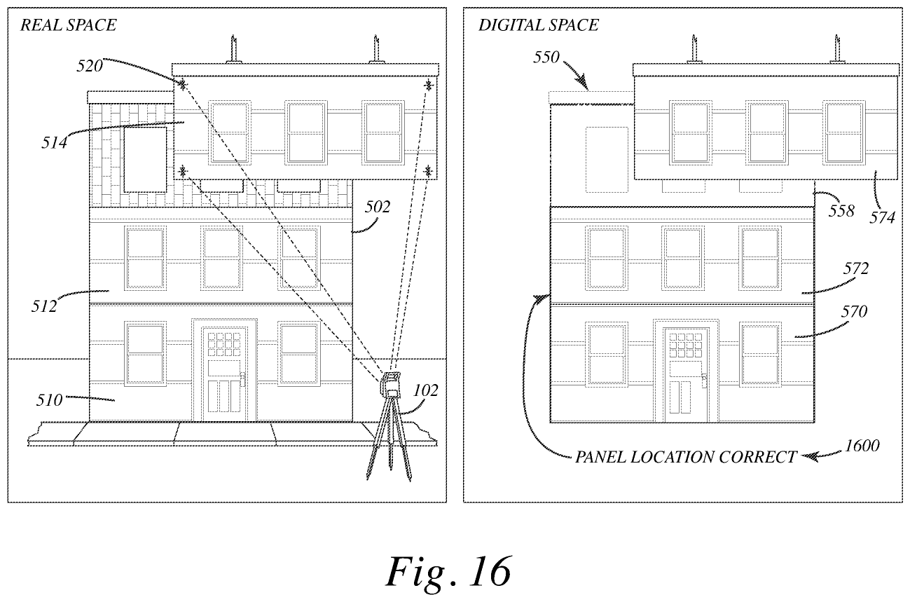

Referring to FIGS. 11-16, optical targets 520 can be temporarily installed on the second panel and a crane or other installation device can begin to move the second panel 512 into its target position 556. Just as with the first panel, the tracking system 102 can track the second panel 512 and communicate position information back to the digital twin manager device. The digital twin manager device can update the position of the panel component 572 of the current digital twin and compare it against the target panel component 556 of the target digital twin and generate instructions for the installation crew to align the panel. Referring to FIG. 12, the digital twin manager device provides an instruction 1200 to the installation crew (e.g., the crane operator), via communication to the positioning assistant system, to “MOVE RIGHT 7 INCHES”. In FIG. 13 an instruction 1300 is provided to “RAISE UP ½ INCH.” In FIG. 14, an instruction 1400 is provided to “PUSH BOTTOM RIGHT CORNER DOWN ⅛ INCH”. In FIG. 15 an instruction is provided to “PUSH IN ½ INCH.” Referring to FIG. 16, once the panel 512 is positioned within certain tolerance ranges for the 6-dimensions (or perhaps fewer in other embodiments), an indication 1600 can be provided to the user that the panel location is correct and the optical targets 520 can be removed from the panel 512.

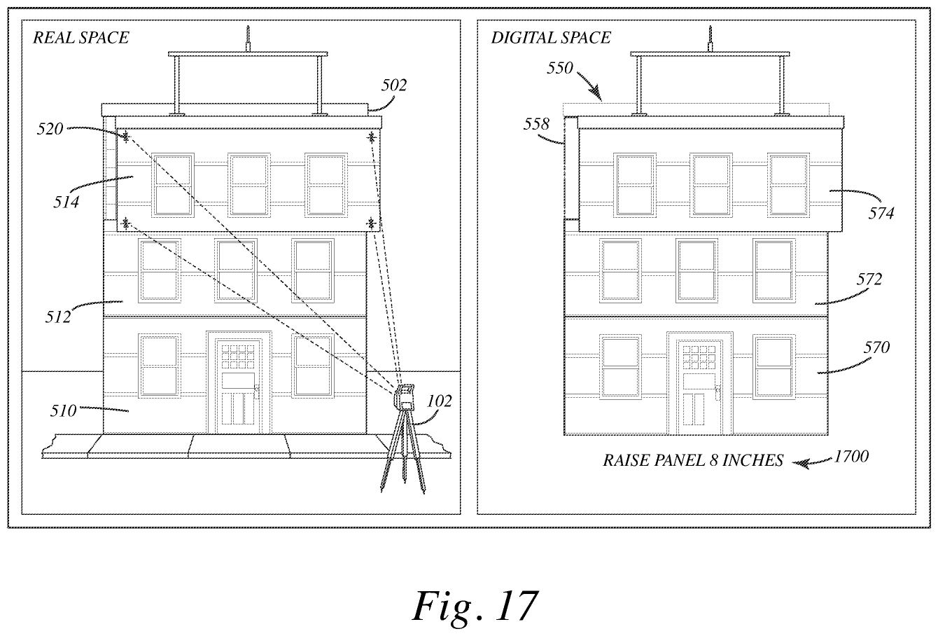

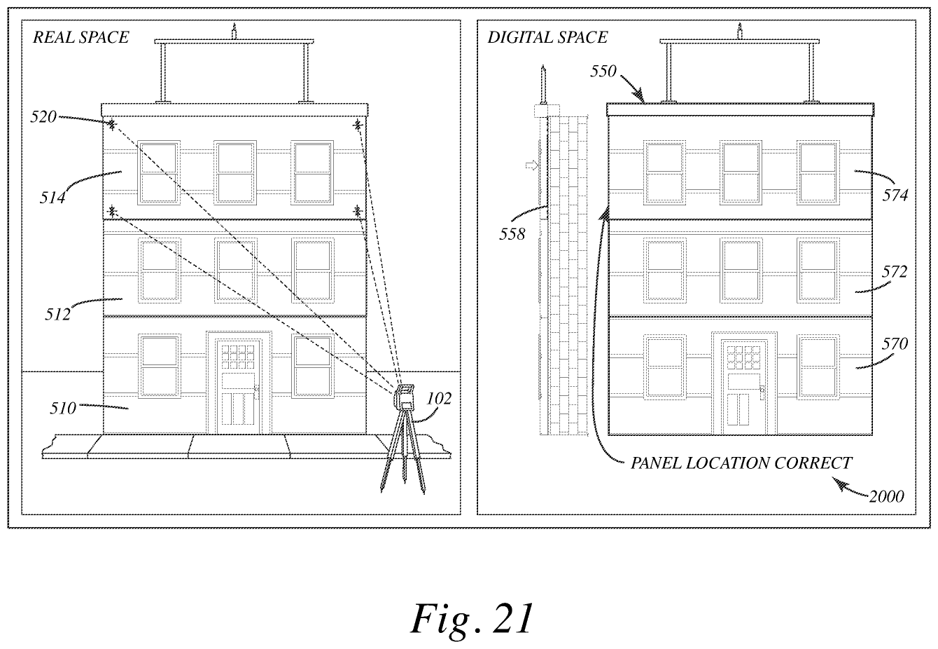

Referring to FIGS. 16-21 optical targets 520 can be temporarily installed on the third panel and a crane or other installation device can begin to move the third panel 514 into its target position 558. Just as with the first two panels, the tracking system 102 can track the third panel 514 and communicate position information back to the digital twin manager device. The digital twin manager device can update the position of the panel component 574 of the current digital twin and compare it against the target panel component 558 of the target digital twin and generate instructions for the installation crew to align the panel. Referring to FIGS. 17-20, the digital twin manager device provides instructions to the installation crew (e.g., the crane operator), via communication to the positioning assistant system, to “RAISE PANEL 8 INCHES” 1700, “MOVE LEFT ¾ INCH” 1800, “PULL RIGHT SIDE UP ⅛ INCH” 1900, and “PUSH IN 1 INCH” 2000. Referring to FIG. 21, once the panel 514 is positioned within certain tolerance ranges for the 6-dimensions (or perhaps fewer in other embodiments), an indication 2100 can be provided to the user that the panel location is correct and the optical targets 520 can be removed from the panel 514.

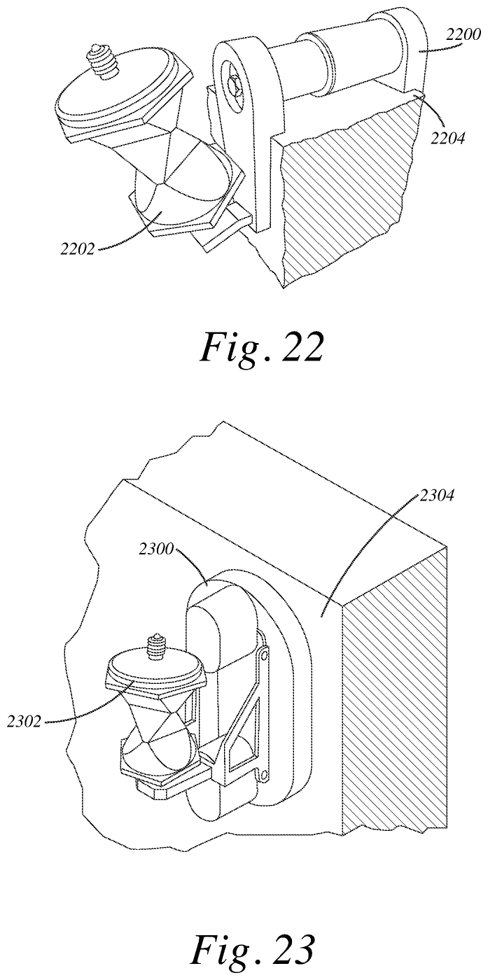

The optical targets can be temporarily mounted to the panels using essentially any mounting system. Two different exemplary mounting systems are illustrated in FIGS. 22-23. FIG. 22 illustrates a mechanical clamp 2200 that can be used to mount a retroreflective target 2202 to the edge of a panel 2204. FIG. 23 illustrates a vacuum fixture mounting system 2300 that can be used to mount a retroreflective target 2302 to the surface 2304 of a panel. Other mounting systems are also suitable. For example, retroreflective tape can be applied to a visible surface of the panel. Alternatively, or additionally, the panel connectors can include optical targets that are applied to their surface or integrated during manufacture.

By utilizing a real-time evaluator of the present disclosure prefab component installation time and cost for new construction or retrofit projects can be reduced by 25% or more. The real-time evaluator can decrease installation issues such as downtime, errors, and scheduling jams. Further, the real-time evaluator can provide enhanced envelope performance by improving installation quality, e.g., by facilitating reduced air leakage and reduced water intrusion.

Directional terms, such as “vertical,” “horizontal,” “top,” “bottom,” “upper,” “lower,” “inner,” “inwardly,” “outer” and “outwardly,” are used to assist in describing the invention based on the orientation of the embodiments shown in the illustrations. The use of directional terms should not be interpreted to limit the invention to any specific orientation(s).

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

The embodiments of the invention in which an exclusive property or privilege is claimed are defined as follows:

1. A system for guiding installation of overclad panels on a building façade, the system comprising:
a machine vision subsystem configured to:
track motion of panel targets relative to façade targets as an overclad panel equipped with the panel targets is being brought towards, and installed at, a predetermined location of the façade equipped with the façade targets, and
output a tracking signal indicative of positions of the panel targets relative to the façade targets;
a controller subsystem communicatively coupled with the machine vision subsystem and configured to:
access, in a data source,
a digital twin of the façade that includes façade local coordinates of the façade targets and of the predetermined installation location,
a digital twin of the overclad panel that includes panel local coordinates of the panel targets, and
an installation tolerance,
receive the tracking signal from the machine vision subsystem,
ascertain, using the façade targets' local coordinates, the panel targets' local coordinates, and the tracking signal, whether the panel is positioned near the predetermined installation location within the installation tolerance, and if not so,
determine a corrective motion of the panel relative to the façade to position the panel nearer the predetermined installation location, and issue corrective motion instructions actionable by an installer of the panel; and
a user interface subsystem communicatively coupled with the controller subsystem and configured to:
receive the corrective motion instructions, and
issue them to the panel installer.

2. The system of claim 1, wherein
the panel targets and façade targets each comprises one or more retroreflectors, and
the machine vision subsystem comprises:
a laser-beam source,
a beam scanning module, and
an imaging module.

3. The system of claim 1, wherein the machine vision subsystem monitors live positions of the panel in six dimensions including X, Y, Z, roll, pitch, and yaw.

4. The system of claim 1, wherein
the user interface subsystem comprises a display module, and
the corrective motion instructions are presented to the panel installer using the display module.

5. The system of claim 1, wherein
the user interface subsystem comprises one or more speakers, and
the corrective motion instructions are presented to the panel installer using the speakers.

6. The system of claim 1, wherein the corrective motion instructions actionable by the installer of the panel include a plurality of sequenced textual based instructions to guide the panel installer in moving the panel to the predetermined location, and wherein each of the plurality of sequenced textual based instructions are limited to instructions to move the panel in one dimension.

7. The system of claim 1, wherein
the façade targets are disposed adjacent to façade connectors, and
the panel targets are disposed adjacent to panel connectors that interlock with the façade connectors when the panel is installed on the façade.

8. The system of claim 1, wherein the panel targets and the façade targets comprise mechanical clamp optical targets.

9. The system of claim 1, wherein the panel targets and the façade targets comprise vacuum fixture optical targets.

10. The system of claim 1, wherein the panel targets are disposed adjacent to panel connectors that interlock with other panel connectors when the panels are installed adjacent to one another.

11. A real-time evaluator for guiding installation of one or more panels relative to a building envelope, the real-time evaluator comprising:
a digital twin manager device configured to receive a target digital twin, the target digital twin including a predetermined arrangement of a virtual representation of a building envelope component and a virtual representation of a panel component;
an autonomous tracking system resectioned in accordance with the target digital twin, the autonomous tracking system configured to:
track motion of panel targets of a panel equipped with the panel targets as the panel is being brought towards, and installed at, a predetermined installation location of the building envelope, and
output a tracking signal indicative of positions of the panel targets;
wherein the digital twin manager device is communicatively coupled with the autonomous tracking system and configured to:
maintain a current digital twin of the panel based on the tracking signal, the current digital twin including a virtual presentation of a panel component; and
determine in six dimensions, based on a comparison between the current digital twin and the target digital twin, the positional variances of the panel component in the current digital twin to the panel component in the target digital twin,
determine a series of corrective motions of the panel relative to the building envelope to position the panel closer to the predetermined installation location, and issue sequential corrective motion instructions actionable by an installer of the panel; and
a position assistance system communicatively coupled with the digital twin manager device and configured to:
receive the corrective motion instructions, and
issue them to the panel installer.

12. The real-time evaluator of claim 8, wherein
the panel targets and building envelope targets each comprises one or more retroreflectors, and
the autonomous tracking system comprises a total robotic station.

13. The real-time evaluator of claim 8, wherein the autonomous tracking system monitors live positions of the panel in six dimensions including X, Y, Z, roll, pitch, and yaw.

14. The real-time evaluator of claim 8, wherein
the position assistance system comprises a display module, and
the corrective motion instructions are presented to the panel installer using the display module.

15. The real-time evaluator of claim 8, wherein
the position assistance system comprises one or more speakers, and
the corrective motion instructions are presented to the panel installer using the speakers.

16. The real-time evaluator of claim 8, wherein the corrective motion instructions actionable by the installer of the panel include a plurality of sequenced textual based instructions to guide the panel installer in moving the panel to the predetermined location, and wherein each of the plurality of sequenced textual based instructions are limited to instructions to move the panel in one dimension.

17. The real-time evaluator of claim 8, wherein the panel targets are disposed adjacent to panel connectors that interlock with the façade connectors when the panel is installed on the façade.

18. The real-time evaluator of claim 8, wherein the panel targets comprise mechanical clamp optical targets.

19. The real-time evaluator of claim 8, wherein the panel targets comprise vacuum fixture optical targets.

20. The real-time evaluator of claim 8, wherein the panel targets are disposed adjacent to panel connectors that interlock with other panel connectors when the panels are installed adjacent to one another.
